(19) United States
(12) Patent Application Publication
(10) Pub. No.: US 2025/0209964 A1
(43) Pub. Date: Jun. 26, 2025

(54) MULTI-DISPLAY DEVICE AND DISPLAY PANEL

(71) Applicant: LG Display Co., Ltd., Seoul (KR)

(72) Inventor: HeeJung HONG, Paju-si (KR)

(73) Assignee: LG Display Co., Ltd., Seoul (KR)

(21) Appl. No.: 18/936,502

(22) Filed: Nov. 4, 2024

(30) Foreign Application Priority Data
Dec. 22, 2023 (KR) 10-2023-0189336

(51) Int. Cl. G09G 3/20; G09G 3/32; G09G 3/3233; G09G 3/3266; G09G 3/3275; G09G 3/36

(52) U.S. Cl. CPC G09G 3/2096; G09G 3/3233; G09G 3/3266; G09G 3/3275; G09G 3/32; G09G 3/3677; G09G 3/3688; G09G 2300/0842; G09G 2320/0233; G09G 2320/045; G09G 2340/0407

(57) ABSTRACT

A multi-display device and a display panel that have a structure in which one controller drives and controls both a transparent display area and an opaque display area, are provided. The transparent display area and the opaque display area are integrated into the display panel. The display panel further includes a plurality of data lines and a plurality of gate lines extending in different directions. The multi-display device and the display panel provide a cost-saving effect.

### CROSS-REFERENCE TO RELATED APPLICATION

This application claims priority to Republic of Korea Patent Application No. 10-2023-0189336, filed on Dec. 22, 2023, in the Korean Intellectual Property Office, the entire contents of which is hereby expressly incorporated by reference into the present application.

### BACKGROUND

### Field

The present disclosure relates to electronic devices with displays, and more specifically, to a multi-display device and a display panel.

### Discussion of the Related Art

As the technology of electronic devices advances, various types of electronic devices are being developed and widely used. In particular, display devices used in various places such as homes, offices, and public places have been increasingly developed in recent years.

As such display devices, liquid crystal displays (LCDs), organic light emitting diode (OLED) displays, micro light emitting diode (micro LED) displays, mini light emitting diode (mini LED) displays, plasma display panel (PDP) displays, quantum dot light emitting diode (QLED) displays, and the like have been developed and increasingly used.

In addition, a multi-display device in which at least one display panel is implemented in various forms has been developed.

The multi-display device can include a type of multi-display apparatus configured to implement one large screen by combining a plurality of display panels.

One example of the multi-display apparatus is a large-screen display apparatus used for exhibiting or advertising in which a plurality of cathode ray tubes are connected to provide a large screen. This type of multi-display device suffers from a disadvantage of poor image quality as images are not naturally connected and disconnected at connection areas between combined unit display panels.

Further, in the case of multi-display device with a large window for exhibiting or advertising, since only one display is insufficient, such a large window has been usually implemented by arranging multiple displays in a tiling method.

As the technology of multi-display devices has been developed, there is a need for transparent display-enabled multi-display devices in order to provide an environment easily viewable from outside for exhibiting or advertising in shops and the like.

In addition, a multi-display device in which a transparent display and a normal display are combined can be used in a variety of ways, such as introducing products, advertising, and the like through a shop window, an entrance door, and the like.

### SUMMARY OF THE DISCLOSURE

To provide such advantages, one or more aspects of the present disclosure can provide a multi-display device that has a structure in which a transparent display area (which herein can be referred to as a light-transmissive display area) and an opaque display area (which herein can be referred to as a light-opaque display area or a normal display area) are configured in one display panel, and is capable of presenting a transparent display in an area of the display panel and a normal display in another area of the display panel.

One or more aspects of the present disclosure can provide a multi-display device that has a structure in which a transparent display area and an opaque display area are configured in one display panel, and provides a wide range of usages, such as product display, entrance doors, windows, and customer consultation displays.

One or more aspects of the present disclosure can provide a multi-display device that has a structure in which one controller drives and controls both a transparent display area and an opaque display area, and thereby has a cost-saving effect.

One or more aspects of the present disclosure can provide a multi-display device configured with various types of displays, such as an LCD, an OLED display, a micro LED display, a mini LED display, a PDP display, a QLED display, and the like.

According to one or more example embodiments of the present disclosure, a multi-display device includes a display panel including a light-transmissive display area disposed in a first area of the display panel and configured to allow external light to be transmitted, and a light-opaque display area disposed in a second area different from the first area, a data driving circuit configured to drive a plurality of data lines across the display panel in a first direction, a gate driving circuit configured to drive a plurality of gate lines across the display panel in a second direction different from the first direction, and a controller configured to supply image data to the data driving circuit.

According to aspects of the present disclosure, a plurality of first pixels defined by the plurality of data lines and the plurality of gate lines can be disposed in a matrix form in the light-opaque display area.

According to aspects of the present disclosure, a plurality of second pixels configured to present an image and a plurality of transmissive areas each disposed on one side of at least one of the plurality of second pixels and configured to allow external light to be transmitted can be disposed in the light-transmissive display area.

According to one or more example embodiments of the present disclosure, a display panel includes a light-opaque display area disposed in a first area, including a plurality of first pixels or pixel groups each including one or more first subpixels, and configured to emit light, a light-transmissive display area disposed in a second area different from the first area, and including a plurality of second pixels or pixel groups each including one or more second subpixels and configured to present an image, and a plurality of transmissive areas each disposed on one side of at least one of the plurality of second pixels or pixel groups and configured to allow external light to be transmitted, a plurality of data lines extending along at least one of the plurality of first pixels and at least one of the plurality of transmissive areas, and a plurality of gate lines extending along one or more first or second pixels in a second direction different from the first direction.

According to one or more aspects of the present disclosure, a multi-display device can be provided that has a structure in which a transparent display area and an opaque display area are configured in one display panel, and is capable of allowing external light to be transmitted and presenting low-resolution images in an area of the display panel, and is capable of presenting high-resolution images in another area of the display panel.

According to one or more aspects of the present disclosure, a multi-display device can be provided that has a structure in which a transparent display area and an opaque display area are configured in one display panel, and provides a wide range of usages, such as product display, entrance doors, windows, and customer consultation displays.

According to one or more aspects of the present disclosure, a multi-display device can be provided that has a structure in which one controller drives and controls both a transparent display area and an opaque display area, and thereby has a cost-saving effect.

According to one or more aspects of the present disclosure, a multi-display device can be provided that is configured with various types of displays, such as an LCD, an OLED display, a micro LED display, a mini LED display, a PDP display, a QLED display, and the like.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 schematically illustrates the configuration of an example display device according to aspects of the present disclosure.

FIG. 2 illustrates an example system configuration of the display device according to aspects of the present disclosure.

FIG. 3 illustrates an example subpixel circuit in the display device according to aspects of the present disclosure.

FIG. 4 schematically illustrates an example multi-display device according to aspects of the present disclosure.

FIGS. 5 to 9 illustrate example arrangements of a light-opaque display area and a light-transmissive display area in the multi-display device according to aspects of the present disclosure.

FIG. 10 schematically illustrates the configuration of an example multi-display device implemented by including at least one LCD panel according to aspects of the present disclosure.

FIG. 11 schematically illustrates the configuration of an example multi-display device implemented by including at least one display panel including light emitting elements, such as OLEDs, micro LEDs, mini LEDs, QLEDs, and the like, according to aspects of the present disclosure.

FIG. 12 illustrates example data driving for the multi-display device according to aspects of the present disclosure.

FIG. 13 schematically illustrates an example arrangement of pixels in a micro LED display device according to aspects of the present disclosure.

FIG. 14. is a flow diagram for an example image display method of the multi- display device according to aspects of the present disclosure.

### DETAILED DESCRIPTION OF THE EMBODIMENTS

Reference will now be made in detail to example embodiments of the present disclosure, examples of which can be illustrated in the accompanying drawings.

In the following description, the structures, embodiments, implementations, methods and operations described herein are not limited to the specific example or examples set forth herein and can be changed as is known in the art, unless otherwise specified. Like reference numerals designate like elements throughout, unless otherwise specified. Names of the respective elements used in the following explanations are selected only for convenience of writing the specification and can thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

In the following description, where the detailed description of the relevant known function or configuration can unnecessarily obscure aspects of the present disclosure, a detailed description of such known function or configuration can be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements can be added unless the term, such as “only,” is used. An element described in the singular form is intended to include a plurality of elements, and vice versa, unless the context clearly indicates otherwise.

Although the terms “first,” “second,” A, B, (a), (b), and the like can be used herein to describe various elements, these elements should not be interpreted to be limited by these terms as they are not used to define a particular order or precedence. These terms are used only to distinguish one element from another, and may not define order or sequence. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may”.

Hereinafter, with reference to the accompanying drawings, various example embodiments of the present disclosure are described in detail. All the components of each display device according to all embodiments of the present disclosure are operatively coupled and configured.

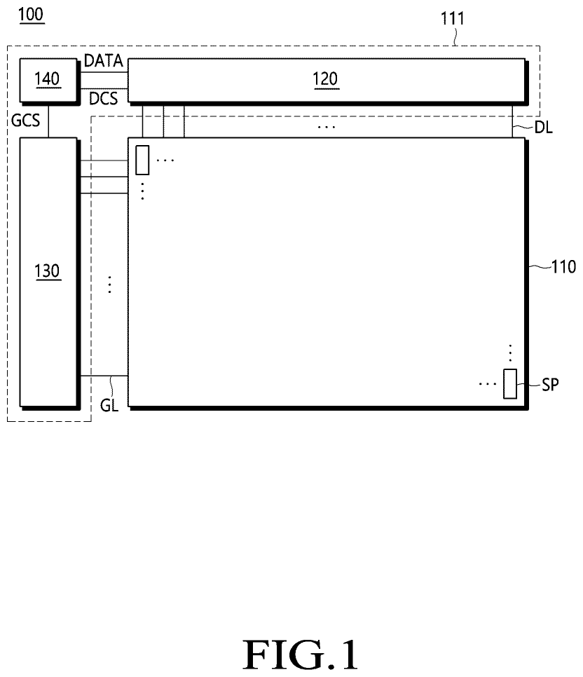

FIG. 1 schematically illustrates the configuration of an example display device 100 according to aspects of the present disclosure.

Referring to FIG. 1, in one or more example embodiments, a display device 100 can include a display panel 110 in which a plurality of data lines DL and a plurality of gate lines GL are disposed, and a plurality of subpixels SP defined by the plurality of data lines DL and the plurality of gate lines GL are disposed in a matrix form, and a driving circuit 111 for driving the display panel 110.

The driving circuit 111 can include a data driving circuit 120 configured to drive the plurality of data lines DL, a gate driving circuit 130 configured to drive the plurality of gate lines GL, and a controller 140 configured to control the data driving circuit 120 and the gate driving circuit 130.

The plurality of data lines DL and the plurality of gate lines GL can be disposed to intersect each other in the display panel 110. In an embodiment, the plurality of gate lines GL can be disposed in rows or columns, and the plurality of data lines DL can be disposed in columns or rows. Hereinafter, for convenience of description and ease of understanding, it is assumed that the plurality of gate lines GL is disposed in rows and the plurality of data lines DL is disposed in columns.

In addition to the plurality of data lines DL and the plurality of gate lines GL, other types of lines can be disposed in the display panel 110.

The controller 140 can supply image data DATA readable by the data driving circuit 120 based on input image data to the data driving circuit 120.

The controller 140 can control operations of the data driving circuit 120 and the gate driving circuit 130 by supplying various types of control signals (DCS, GCS) needed for operating or driving the data driving circuit 120 and the gate driving circuit 130.

The controller 140 can start scan operation according to a respective time processed for each frame, convert image data inputted from an image providing source to a data signal form readable by the data driving circuit 120 and then supply image data DATA resulting from the converting to the data driving circuit 120, and control the loading of the data to at least one pixel at a predefined time according to a scan process.

To control the data driving circuit 120 and the gate driving circuit 130, the controller 140 can receive several types of timing signals including a vertical synchronous signal VSYNC, a horizontal synchronous signal HSYNC, an input data enable signal DE, a clock signal CLK, and the like from an internal or external timing signal providing source (e.g., a host system), generate several types of control signals (DCS and GCS), and output the generated signals (DCS and GCS) to the data driving circuit 120 and the gate driving circuit 130.

For example, to control the gate driving circuit 130, the controller 140 can output several types of gate control signals GCS including a gate start pulse GSP, a gate shift clock GSC, a gate output enable signal GOE, and the like.

Further, to control the data driving circuit 120, the controller 140 can output several types of data control signals DCS including a source start pulse SSP, a source sampling clock SSC, a source output enable (SOE) signal, and the like.

The controller 140 can be a timing controller used in the typical display technology or a control apparatus/device capable of additionally performing other control functionalities in addition to the typical function of the timing controller.

The controller 140 can be implemented as a separate component from the data driving circuit 120, or integrated with the data driving circuit 120 and thus implemented in a single integrated circuit.

The data driving circuit 120 can drive a plurality of data lines DL by supplying data voltages corresponding to image data DATA received from the controller 140 to the plurality of data lines DL. Here, the data driving circuit 120 is sometimes referred to as a source driving circuit or a source driver.

The data driving circuit 120 or each source driver integrated circuit SDIC can include a shift register, a latch circuit, a digital-to-analog converter DAC, an output buffer, and the like.

In one or more aspects, the data driving circuit 120 can further include one or more analog-to-digital converters ADC.

The gate driving circuit 130 can sequentially drive a plurality of gate lines GL by sequentially supplying scan signals to the plurality of gate lines GL. Here, the gate driving circuit 130 is sometimes referred to as a scan driving circuit or a scan driver.

The gate driving circuit 130 can include a shift register, a level shifter, and the like.

The gate driving circuit 130 can sequentially supply scan signals with an on-voltage level or an off-voltage level to the plurality of gate lines GL by control of the controller 140.

When a specific gate line is selected and driven by a scan signal from the gate driving circuit 130, the data driving circuit 120 can convert image data DATA received from the controller 140 into analog data voltages and supply the obtained data voltages to the plurality of data lines DL.

The data driving circuit 120 can be located in, and/or electrically connected to, but not limited to, only one side or portion (e.g., an upper edge or a lower edge) of the display panel 110. In one or more aspects, the data driving circuit 120 can be located in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or other design requirements.

The gate driving circuit 130 can be located in, and/or electrically connected to, but not limited to, only one side or portion (e.g., a left edge or a right edge) of the display panel 110. In one or more aspects, the gate driving circuit 130 can be located in, and/or electrically connected to, but not limited to, two sides or portion (e.g., a left edge and a right edge) of the display panel 110 or at least two of four sides or portions (e.g., the right edge, the right edge, an upper edge, and a lower edge) of the display panel 110 according to driving schemes, panel design schemes, or other design requirements.

In one or more aspects, the data driving circuit 120 can include at least one source driver integrated circuit SDIC.

In one or more aspects, each source driver integrated circuit SDIC can be connected to the display panel 110 by a tape-automated-bonding (TAB) technique, or connected to a conductive pad such as a bonding pad of the display panel 110 by a chip-on-glass (COG) technique. In one or more aspects, each source driver integrated circuit SDIC can be integrated into one or more other components or circuits and disposed in the display panel 110. In one or more aspects, each source driver integrated circuit SDIC can be connected to the display panel 110 by a chip-on-film (COF) technique. In this implementation, each source driver integrated circuit SDIC can be mounted on a circuit film, and be electrically connected to data lines DL in the display panel 110 through the circuit film.

In one or more aspects, the gate driving circuit 130 can include at least one gate driver integrated circuit GDIC connected to the display panel 110 by the tape-automated-bonding (TAB) technique or connected to a conductive pad such as a bonding pad of the display panel 110 by the chip-on-glass (COG) technique. In one or more aspects, the gate driving circuit 130 can be disposed in the display panel 110 by a gate-in-panel (GIP) technique. For example, the gate driving circuit 130 can be embedded into the display panel 110 by the gate-in-panel (GIP) technique. In one or more aspects, the gate driving circuit 130 can be connected to the display panel 110 by the chip-on-film (COF) technique. In this implementation, each gate driver integrated circuit GDIC included in the gate driving circuit 130 can be mounted on a circuit film, and be electrically connected to gate lines GL in the display panel 110 through the circuit film.

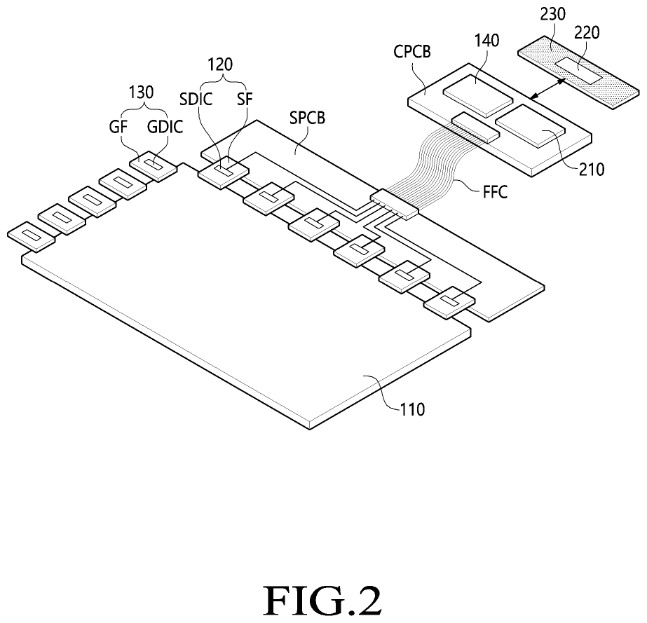

FIG. 2 illustrates an example system configuration of the display device 100 according to aspects of the present disclosure.

It should be noted that FIG. 2 illustrates an example where each source driver integrated circuit SDIC included in the data driving circuit 120 is implemented by the chip-on-film (COF) technique among various techniques (TAB, COG, COF, and the like), and the gate driving circuit 130 is implemented by the gate-in-panel (GIP) technique among various techniques (TAB, COG, COF, GIP, and the like).

Referring to FIG. 2, each of a plurality of source driver integrated circuits SDIC included in the data driving circuit 120 can be mounted on a corresponding source-side circuit film SF of a plurality of source-side circuit films SF.

One side of each source-side circuit film SF can be electrically connected to the display panel 110.

One or more lines for electrically connect each source driver integrated circuit SDIC and the display panel 110 can be disposed on a corresponding the source side circuit film SF.

For electrical connections between the source driver integrated circuits SDIC and one or more other components or devices, the display device 100 can include at least one source printed circuit board SPCB and a control printed circuit board CPCB allowing control components and several types of electric components or devices to be mounted.

A first side of each source-side circuit film SF on which a corresponding source driver integrated circuit SDIC is mounted can be connected to the at least one source printed circuit board SPCB.

For example, a second opposing side of the source-side circuit film SF on which the source driver integrated circuit SDIC is mounted can be electrically connected to the display panel 110, and the first side can be electrically connected to the at least one source printed circuit board SPCB.

In one or more aspects, the controller 140 configured to control operations of the data driving circuit 120 and the gate driving circuit 130, a power management integrated circuit PMIC configured to supply various voltages or currents, or control various voltages or currents to be supplied, to the display panel 110, the data driving circuit 120, the gate driving circuit 130, and the like, and the like can be mounted on the control printed circuit board CPCB.

The at least one source printed circuit board SPCB and the control printed circuit board CPCB can have a circuit connection through at least one connection member. For example, the connection member can include a flexible printed circuit FPC, a flexible flat cable FFC, and the like.

In one or more aspects, the at least one source printed circuit board SPCB and the control printed circuit board CPCB can be integrated and implemented as one printed circuit board.

The display device 100 can further include a set board 230 electrically connected to the control printed circuit board CPCB. The set board 230 can be referred to as a power board.

This set board 230 can include a main power management circuit 220 configured to manage all or some of power (e.g., voltages, currents, and the like) used in the display device 100.

In one or more aspects, the power management integrated circuit 210 can be a circuit configured to manage power (e.g., voltages, currents, and the like) for a display module including the display panel 110 and driving circuits (120, 130, 140, and the like) for driving the display panel 110, and the main power management circuit 220 can be a circuit configured to manage overall power (e.g., voltages, currents, and the like) for the display device 100 including the power for the display module, and be interoperable with the power management integrated circuit 210.

In one or more aspects, in an example where the display device 100 is a self-emission display device, each of subpixels SP disposed in the display panel 110 can include a self-emission light emitting element such as an organic light emitting diode OLED, and circuit elements such as one or more transistors including a driving transistor, and the like for driving an the self-emission light emitting element.

Types of circuit elements and the number of the circuit elements included in each subpixel SP can be different depending on types of the panel (e.g., an LCD panel, an OLED panel, etc.), provided functions, design schemes/features, or the like.

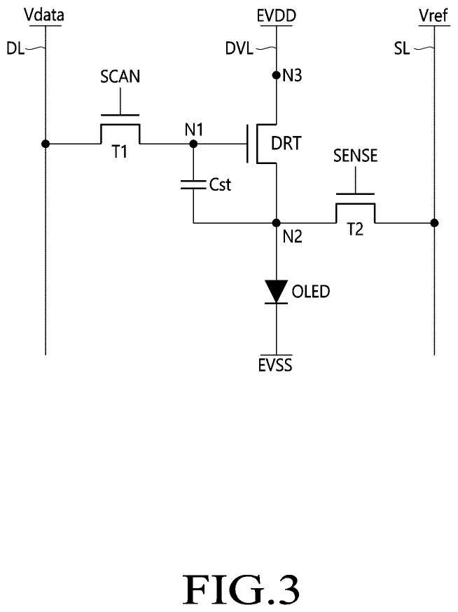

FIG. 3 illustrates an example subpixel circuit in the display device 100 according to aspects of the present disclosure.

Referring to FIG. 3, in one or more aspects, a plurality of data lines DL, a plurality of gate lines GL, a plurality of driving voltage lines DVL, and a plurality of sensing lines SL can be disposed in the display panel 110.

Each of subpixels SP disposed in the display panel 110 can include a light emitting element, such as an OLED, a micro LED, a mini LED, a QLED, and the like, a driving transistor DRT configured to drive the light emitting element, a first transistor T1 electrically connected between a first node N1 of the driving transistor DRT and a data line DL, a second transistor T2 electrically connected between a second node N2 of the driving transistor DRT and a corresponding sensing line SL among a plurality of sensing lines SL, a storage capacitor Cst electrically connected between the first node N1 and the second node N2 of the driving transistor DRT, and the like.

In an example where the light emitting element is implemented as an organic light emitting diode OLED, the organic light emitting diode OLED can include an anode electrode, an organic emission layer, a cathode electrode, and the like.

Particularly, FIG. 3 illustrates that the anode electrode of the organic light emitting diode OLED can be electrically connected to the second node N2 of the driving transistor DRT. A base voltage EVSS such as a ground voltage, and the like can be applied to the cathode electrode of the organic light emitting diode OLED.

The base voltage EVSS can be, for example, a ground voltage, a low voltage, or a voltage higher or lower than, or similar to, the ground voltage. The base voltage EVSS can vary depending on driving states. For example, the base voltage EVSS at the time of image driving can be set differently from the base voltage EVSS at the time of sensing driving.

The driving transistor DRT can drive the organic light emitting diode OLED by allowing a driving current to flow through the organic light emitting diode OLED.

The driving transistor DRT can include the first node N1, the second node N2, and a third node N3.

The first node N1 of the driving transistor DRT can be a gate node and be electrically connected to the source node or drain node of the first transistor T1. The second node N2 of the driving transistor DRT can be a source node or a drain node. The second node N2 of the driving transistor DRT can be electrically connected to the anode electrode (or cathode electrode) of the organic light emitting diode OLED, and can be also electrically connected to the source node or the drain node of the second transistor. The third node N3 of the driving transistor DRT can be the drain node or the source node. A driving voltage EVDD can be applied to the third node N3 of the driving transistor DRT, and a driving voltage line DVL for delivering the driving voltage EVDD can be electrically connected to the third node N3 of the driving transistor DRT. Hereinafter, for merely convenience of explanation, discussions can be provided based on examples where the first, second, and third nodes (N1, N2, and N3) of the driving transistor DRT are gate, source, and drain nodes, respectively. However, example embodiments of the present disclosure are not limited thereto.

The storage capacitor Cst can be electrically connected between the first node N1 and the second node N2 of the driving transistor DRT, and can maintain a data voltage Vdata corresponding to an image signal voltage or image data during one frame time (or a preset time).

The drain node or source node of the first transistor T1 can be electrically connected to the data line DL, and the source node or drain node of the first transistor T1 can be electrically connected to the first node N1 of the driving transistor DRT. The gate node of the first transistor T1 can be electrically connected to a gate line, and a scan signal SCAN can be applied to the gate node.

The first transistor T1 can be turned on or turned off by the scan signal SCAN delivered through the gate line.

The first transistor T1 can be turned on by the scan signal SCAN and allow a data voltage Vata delivered through the data line DL to be applied to the first node N1 of the driving transistor DRT.

The drain node or source node of the second transistor T2 can be electrically connected to the sensing line SL, and the source node or drain node of the second transistor T2 can be electrically connected to the second node of the driving transistor DRT. The gate node of the second transistor T2 can be electrically connected to the gate line or another gate line, and a sense signal SENSE can be applied to the gate node.

The second transistor T2 can be turned on or turned off by the sense signal SCAN delivered through the gate line.

The second transistor T2 can be turned on by the sense signal SENSE and allow a reference voltage Vref delivered through the sensing line SL to be applied to the second node N2 of the driving transistor DRT.

The storage capacitor Cst can be an external capacitor intentionally designed to be located outside of the driving transistor DRT, and therefore, be different from an internal capacitor such as a parasitic capacitor (e.g., a Cgs, a Cgd) that can be formed between the first node N1 and the second node N2 of the driving transistor DRT.

Each of the driving transistor DRT, the first transistor T1, and the second transistor T2 can be an n-type transistor or a p-type transistor.

In one or more aspects, the scan signal SCAN and the sense signal SENSE can be separate gate signals. In this implementation, the scan signal SCAN and the sense signal SENSE respectively can be applied to the gate node of the first transistor T1 and the gate node of the second transistor T2 through different gate lines.

In one or more aspects, the scan signal SCAN and the sense signal SENSE can be the same gate signal. In this implementation, the scan signal SCAN and the sense signal SENSE can be commonly applied to the gate node of the first transistor T1 and the gate node of the second transistor T2 through the same gate line.

It should be understood that the sub-pixel structure with two transistors (3T) and one capacitor (1C) shown in FIG. 3 is merely one example of possible sub-pixel structures for convenience of discussion, and embodiments of the present disclosure can be implemented in any of various structures, as desired. For example, the sub-pixel can further include at least one transistor and/or at least one capacitor. In some embodiments, each of a plurality of sub-pixels can have the same structure, or some of the plurality of sub-pixels can have a different structure.

Hereinafter, image driving operation of each subpixel is briefly discussed.

The display driving (which can be also referred to as image driving) operation of each subpixel SP can include an image data writing stage, a boosting stage, and a light emitting stage.

In the image data writing stage, an image driving data voltage Vdata corresponding to an image signal can be applied to the first node N1 of the driving transistor DRT, and an image driving reference voltage Vref can be applied to the second node N2 of the driving transistor DRT. It should be noted that due to resistance properties between the second node N2 of the driving transistor DRT and the sensing line SL, a voltage Vref′ similar to the reference voltage Vref can be applied to the second node N2 of the driving transistor DRT.

The reference voltage Vref for image driving can be referred to as VpreR.

In the image data writing stage, the first transistor T1 and the second transistor T2 can be turned on simultaneously or at a slight time difference.

In the image data writing stage, electric charges corresponding to a potential difference (Vdata−Vref or Vdata−Vref′) between both terminals can be stored in the storage capacitor Cst.

The applying of the image driving data voltage Vdata to the first node N1 of the driving transistor DRT can be referred to as image data writing.

In the boosting stage following the image data writing stage, the first and second nodes N1 and N2 of the driving transistor DRT can be electrically floated simultaneously or at a slight time difference.

In order for this operation to be performed, the first transistor T1 can be turned off by a turn-off level voltage of the scan signal SCAN. Further, the second transistor T2 can be turned off by a turn-off level voltage of the sense signal SENSE.

In the boosting stage, as a voltage difference between the first and second nodes (N1 and N2) of the driving transistor DRT is remained, respective voltages in the first and second nodes (N1 and N2) of the driving transistor DRT can be boosted.

After voltages in the first and second nodes (N1 and N2) of the driving transistor DRT through the boosting stage are boosted, when a voltage in the second node N2 of the driving transistor DRT becomes equal to or greater than a certain value (i.e., as a voltage capable of turning on the organic light emitting diode OLED, a voltage as great as the threshold voltage of the organic light emitting diode OLED from the base voltage EVSS), the display driving operation can move to the light emitting stage.

In the light emitting stage, a driving current can flow across the organic light emitting diode OLED. Thereby the organic light emitting diode OLED can emit light.

Driving transistors DRT disposed in a plurality of subpixel SP disposed in the display panel 110 have unique characteristic values (herein, characteristics and characteristic values can be used interchangeably) such as a threshold voltage, mobility, and the like.

However, since the driving transistors DRT can age over driving times. Therefore, the unique characteristic values of the driving transistors DRT can vary over time.

When the characteristic values of the driving transistors DRT vary, on and/or off timings of the driving transistors can vary or capabilities of driving organic light emitting diodes OLED can vary. For example, as the characteristic values of the driving transistors DRT vary, timings for providing currents to the organic light emitting diodes OLED and amounts of current provided to the organic light emitting diodes OLED can vary. As a result, actual luminance of corresponding subpixels SP can be different from intended luminance thereof depending on variances in the characteristic values of the driving transistors DRT.

Further, the plurality of subpixels SP disposed in the display panel 110 can have respective driving timings different from each other. Accordingly, a difference in characteristic values (a difference in threshold voltages, a difference in mobility, and the like) between driving transistors DRT of subpixels SP can occur.

Such a difference in characteristic values between the driving transistors DRT can cause a difference in luminance between subpixels SP. Thereby, the luminance uniformity of the display panel 110 can become poor, in turn, this leading image quality to become poor.

To address these issues, the display device 100 can include a compensation circuit for compensating for a difference in one or more characteristic values of driving transistors DRT, and provide a method of performing compensation based on the compensation circuit.

Meanwhile, a typical multi-display device configured with a plurality of display panels has been developed to provide one large screen.

However, in a case where multiple display panels are combined to implement such a multi-display device, the multi-display device can be suffered from a disadvantage of poor image quality as images are not naturally connected and disconnected at connection areas between combined unit display panels.

As the technology of multi-display devices has been developed, there is a need for transparent display-enabled multi-display devices in order to provide an environment easily viewable from outside for exhibiting or advertising in shops and the like.

In addition, a multi-display device in which a transparent display and a normal display are combined can be used in a variety of ways, such as introducing products, advertising, and the like through a shop window, an entrance door, and the like.

To address the foregoing issues and provide such advantages, one or more example embodiments of the present disclosure can provide a multi-display device that has a structure in which a transparent display area and an opaque display area are configured in one display panel, and is capable of presenting a transparent display in an area of the display panel and a normal display in another area of the display panel.

In the multi-display device according to example embodiments of the present disclosure, one controller can drive and control both the transparent display area and the opaque display area, and thereby provide a cost-saving effect.

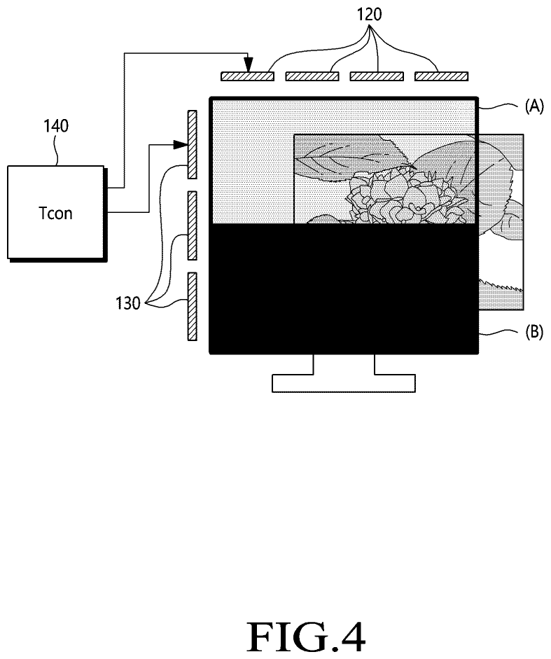

Hereinafter, example multi-display devices according to example embodiments of the present disclosure are described in more detail with reference to FIGS. 4 to 13.

FIG. 4 schematically illustrates an example multi-display device according to aspects of the present disclosure.

Referring to FIG. 4, in one or more aspects, a multi-display device 100 can include a display panel 110, a data driving circuit 120, a gate driving circuit 130, and the like.

The display panel 110 can include a light-transmissive display area A disposed in a first area and a light-opaque display area B disposed in a second area different from the first area.

A plurality of second pixels 510 each including second subpixels configured with light emitting elements such as OLEDs, micro LEDs, mini LEDs, QLEDs, and the like to present an image and a plurality of transmissive areas 520 each disposed on one side of at least one of the plurality of second pixels 510 and configured to allow external light to be transmitted can be disposed in the light-transmissive display area A.

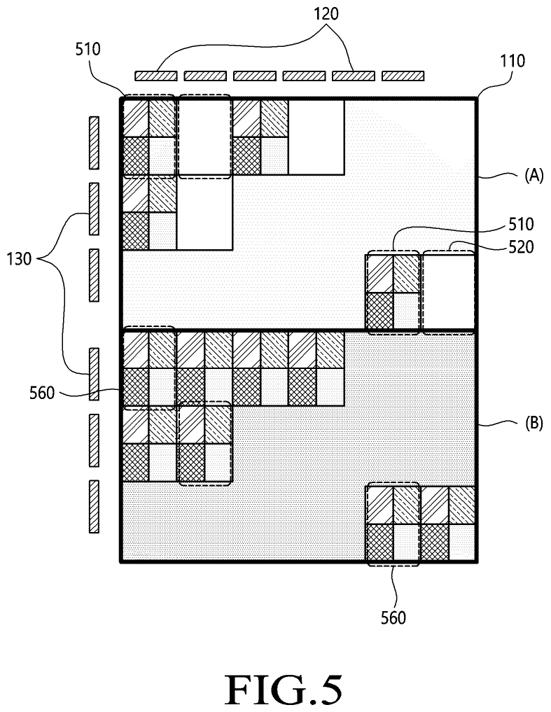

FIGS. 5 to 9 illustrate example arrangements of a light-opaque display area and a light-transmissive display area defined in the multi-display device according to aspects of the present disclosure.

Referring to FIG. 5, all or at least some of a plurality of second pixels and all or at least some of a plurality of transmissive areas disposed in a light-transmissive display area A can be disposed alternately and/or disposed adjacent to each other in the display panel 110.

In one or more aspects, the plurality of second pixels 510 and the plurality of transmissive areas 520 can be alternately disposed on a one-by-one basis in a second direction (e.g., a row direction or a direction in which gate lines extend).

In one or more aspects, the plurality of second pixels 510 and the plurality of transmissive areas 520 can be alternately disposed on a one-by-one basis in a first direction (e.g., a column direction or a direction in which data lines extend).

In one or more aspects, the plurality of second pixels 510 and the plurality of transmissive areas 520 can be alternately disposed on a two or more-by-two or more basis in the first direction and the second direction.

Each second pixel can include a plurality of second subpixels each including elements such as one or more thin film transistors, one or more capacitors, and a light emitting element, such as an OLED, a micro LED, a mini LED, a QLED, and the like, and the like, and be configured to emit light corresponding to an image signal or image data through the light emitting element.

Each transmissive area 520 can be a pixel configured to allow external light to be transmitted, and not include elements such as a thin film transistor, a capacitor, and a light emitting element, and the like. Thus, as each transmissive area 520 does not emit light, the transmissive areas 520 can be referred to as dummy pixels.

Since the light-transmissive display area A includes the second pixels 510 configured to present images and the transmissive areas 520 configured to allow external light to be transmitted, when not viewing an image displayed on the display panel 110, a user can view an external image through the light-transmissive display area A.

According to the configuration of FIG. 5, since elements, such as a thin film transistor, a capacitor, and a light emitting element, and the like, are not disposed in the transmissive area 520, the transmittance of external light passing through the transmissive area 520 can be maximized, and in turn, the transmittance of external light passing through the entire display panel 110 can be improved. Further, the distortion of a transmitted image caused by interference with the elements, such as a thin film transistor, a capacitor, and an organic light emitting element, and the like, can be minimized.

The light-opaque display area B can be an area in which first subpixels configured with light emitting elements, such as OLEDs, micro LEDs, mini LEDs, QLEDs, and the like to emit light are disposed. For example, each of subpixels included in the at least one first pixel 560 disposed in the light-opaque display area B can include elements, such as one or more thin film transistors, one or more capacitors, and a light emitting element such as an OLED, a micro LED, a mini LED, a QLED, and the like, and the like, and can emit light corresponding to a data signal or image data based on these elements. The light-opaque display area B in which the first pixels 560 are disposed may not include a transmissive area allowing external light to be transmitted.

Unlike the light-transmissive display area A, since the light-opaque display area B is an opaque area not including a transmissive area through which external light passes, thus, light cannot pass through this area, and a user cannot see objects or images located on the opposite side.

In one or more aspects, as shown in FIG. 5, the light-transmissive display area A can be located at an upper portion of the display panel 110, and the light-opaque display area B can be located at a lower portion of the display panel 110.

In one or more aspects, contrary to the example of FIG. 5, the light-transmissive display area A can be located at a lower portion of the display panel 110, and the light-opaque display area B can be located at an upper portion of the display panel 110.

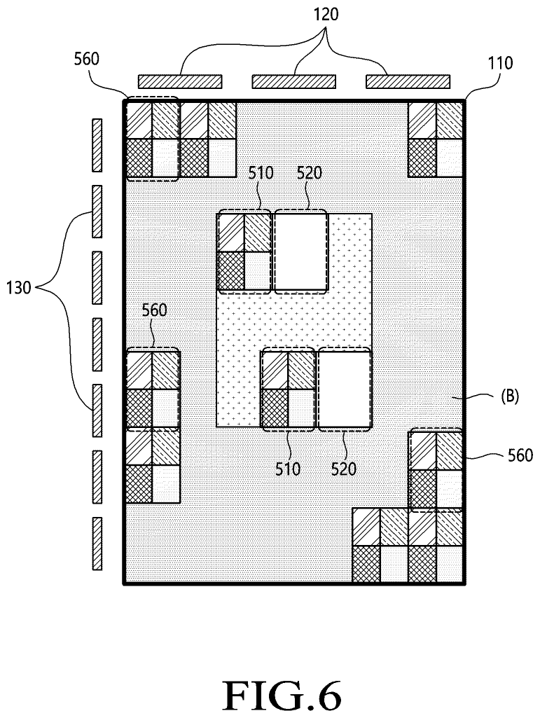

In one or more aspects, as shown in FIG. 6, the light-transmissive display area A can be located at a central portion of the display panel 110, and the light-opaque display area B can be located at one or more areas other than the central portion, for example, one or more side or edge portions of the display panel 110.

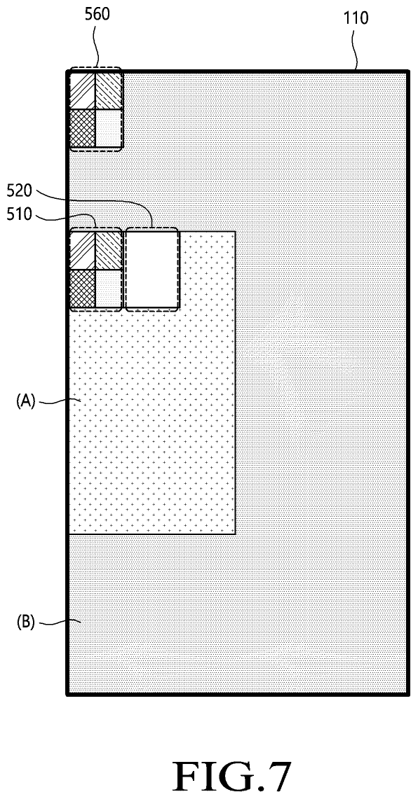

In one or more aspects, as shown in FIG. 7, the light-transmissive display area A can be located at one or more side or edge portions of the display panel 110, and the light-opaque display area B can be located at one or more side or edge portions of the display panel 110 other than the one or more side or edge portions in which the light-transmissive display area A is located.

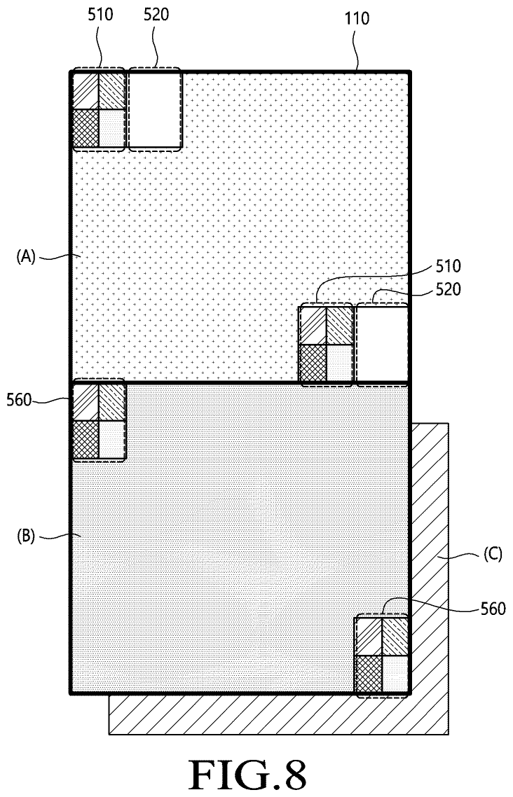

As shown in FIG. 8, the multi-display device 100 can include one or more circuits and a battery C located on the back of the light-opaque display area B. In this example, as the one or more circuits and the battery C are not disposed on the back of the light-transmissive display area A, but are disposed on the back of the light-opaque display area B, thereby, the multi-display device 100 can have an advantage of maintaining the transparency of the light-transmissive display area A.

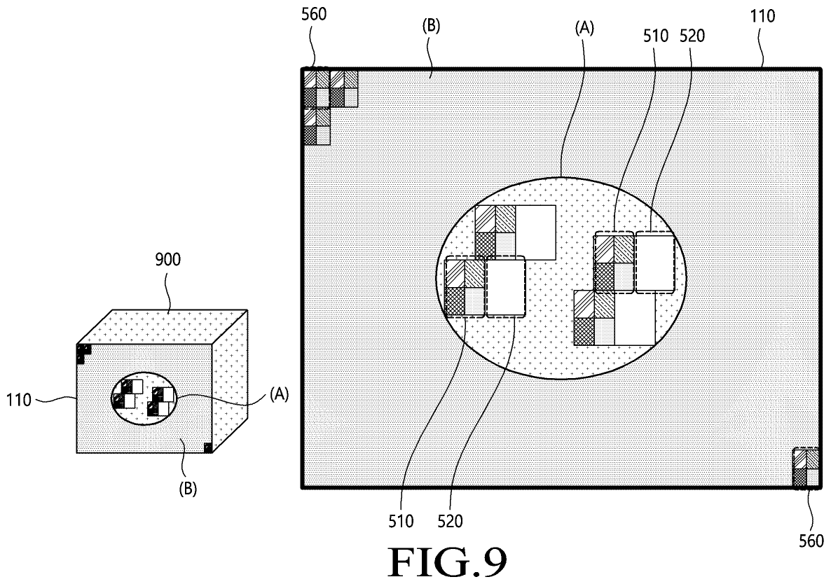

As shown in FIG. 9, a light-transmissive display area A can be disposed in the central portion of the display panel 110, and a transmissive window with a shape, such as a circle, oval, or the like, can be disposed at the light-transmissive display area A in the entire area of the multi-display device 100. In this implementation, a light-opaque display area B can be disposed in the remaining area of the multi-display device 100 except for the light-transmissive display area A.

In one or more aspects, a plurality of light-transmissive display areas A and a plurality of light-opaque display areas B can be configured to intersect each other in the display panel 110.

For example, a plurality of light-transmissive display areas A (“area A”) and a plurality of light-opaque display areas B (“area B”) can be arranged in the display panel 110 in an alternate arrangement pattern, such as, from the top to the bottom of the display panel 110, in the order of area A-area B-area A-area B, area B-area A-area B, area B-area A-area B-area A, or the like. In this implementation, the number of pixels included in each of the plurality of light-transmissive display areas A can be different or the same, and the number of pixels included in each of the plurality of light-opaque display areas B can be different or the same. Further, the number of pixels included in each of the plurality of light-transmissive display areas A and the number of pixels included in each of the plurality of light-opaque display areas B can be different or the same.

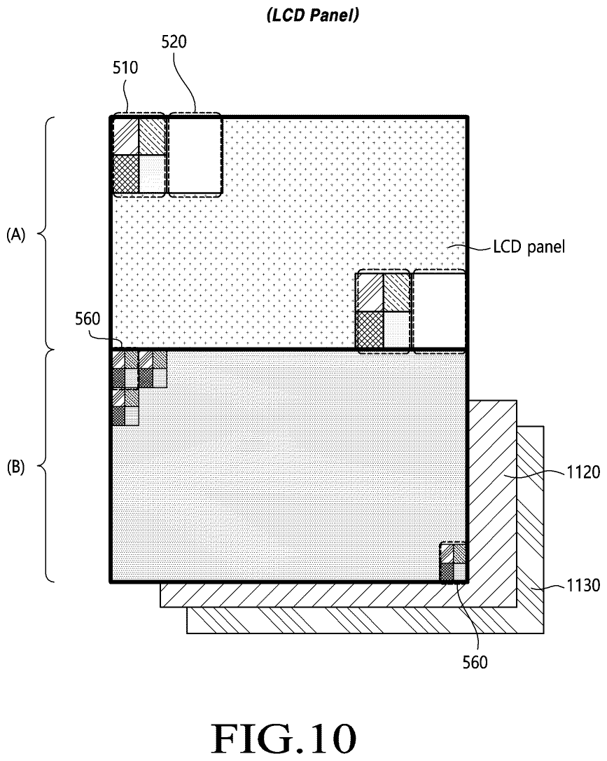

FIG. 10 schematically illustrates the configuration of an example multi-display device implemented by including at least one LCD panel according to aspects of the present disclosure.

Referring to FIG. 10, when a multi-display device is configured with at least one LCD panel, while at least one second pixel 510 disposed in an LCD panel area can include color filters, at least one transmissive area 520 may not include a color filter.

Accordingly, when ambient light enters the multi-display device, some of the light can be transmitted through the at least one transmissive area 520, and therefore, the LCD panel area can serve as a light-transmissive display area A.

A light-opaque display area B, which is attached to or combined with one side of at least one LCD panel and configured to form the multi-display, can be an area where at least one first pixel 560 configured with light emitting elements, such as OLEDs, micro LEDs, mini LEDs, QLEDs, and the like, to emit light is disposed. For example, each of subpixels included in the at least one first pixel 560 disposed in the light-opaque display area B can include elements, such as one or more thin film transistors, one or more capacitors, and a light emitting element such as an OLED, a micro LED, a mini LED, a QLED, and the like, and the like, and can emit light corresponding to a data signal or image data based on these elements. The light-opaque display area B in which the at least one first pixel 560 is disposed may not include a pixel (e.g., a dummy pixel or a light-transmissive area) allowing external light to be transmitted.

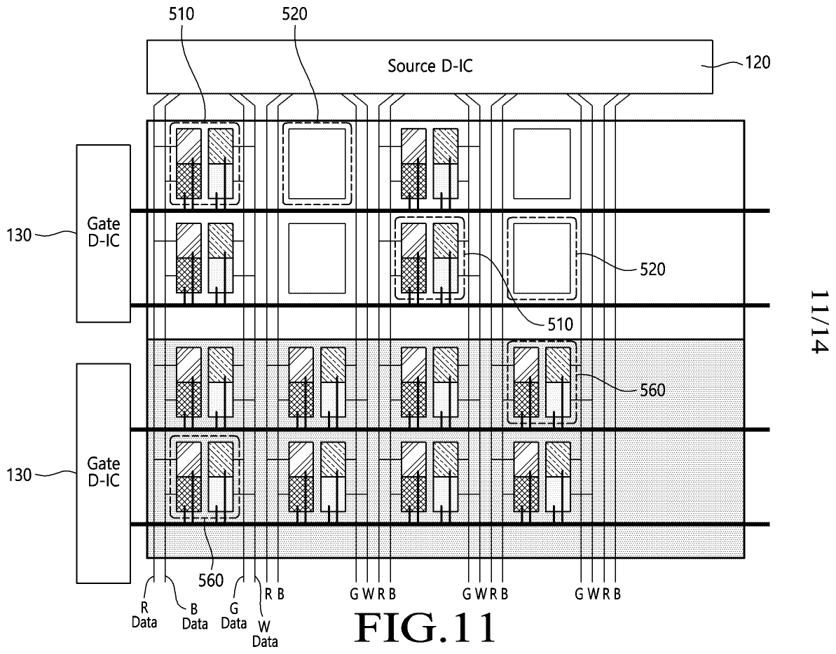

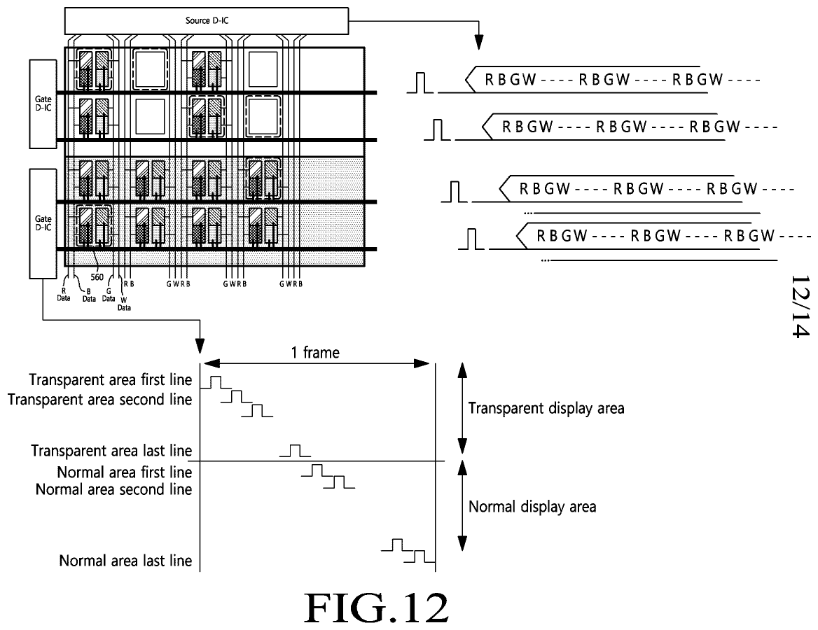

FIG. 11 schematically illustrates an example configuration of a multi-display device implemented by including the display panel 110 configured with light emitting elements, such as OLEDs, micro LEDs, mini LEDs, QLEDs, and the like, or the display device 100 including the display panel 110 according to aspects of the present disclosure. FIG. 12 illustrates example data driving for the multi-display device according to aspects of the present disclosure.

Referring to FIG. 11, a first gate driving circuit 130 can sequentially drive a plurality of gate lines GL connected to one or more pixels disposed in a light-transmissive display area A by sequentially supplying a gate signal with a turn-on level voltage to the plurality of gate lines GL, and a second gate driving circuit 130 can sequentially drive a plurality of gate lines GL connected to one or more pixels disposed in a light-opaque display area B by sequentially supplying a gate signal with a turn-on level voltage to the plurality of gate lines GL. For example, the first gate driving circuit 130 and the second gate driving circuit 130 can be separate gate driving circuits, or respective circuit portions or different gate driver integrated circuits included in a single gate driving circuit.

For example, a plurality of gate lines GL can be connected to one or more second pixels 510 or be connected to scan signal lines connected to the one or more second pixels 510. Further, a plurality of gate lines GL can be connected to one or more first pixels 560 or be connected to scan signal lines connected to the one or more first pixels 560.

The plurality of gate lines GL connected to the one or more second pixels 510 or the scan signal lines connected to the one or more second pixels 510 can extend in the row direction without being connected to one or more transmissive areas 520. For example, one or more dummy pixels, which are respectively configured in the one or more transmissive areas 520, may not be electrically connected to the gate lines GL.

When one or more specific gate lines are selected and driven by the gate driving circuit 130, the data driving circuit 120 can convert image data received from the controller 140 into analog data signals and supply the data signals resulting from the converting to at least one of a plurality of data lines DL.

In one or more aspects, one or more subpixels included in the light-transmissive display area A and one or more subpixels included in the light-opaque display area B can be electrically connected to a data line DL in the column direction. The data driving circuit 120 can sequentially output data voltages or data signals to be supplied to subpixels disposed in the column direction to one data line DL.

The data line DL connected to at least one subpixel included in at least one second pixel 510 and at least one subpixel included in at least one first pixel 560 can deliver data signals corresponding to image data to the at least one subpixel of the at least one second pixel 510 and the at least one subpixel of the at least one first pixel 560.

In contrast, a data line DL connected to at least one first pixel disposed in a same column as at least one transmissive area 520 can extend in the column direction without being electrically connected to the at least one transmissive area 520. For example, one or more dummy pixels, which are respectively configured in the one or more transmissive areas 520 may not be electrically connected to the data line DL.

Referring to FIG. 12, in one or more aspects, a multi-display device can be configured with a structure where at least one light-transmissive display area A and at least one light-opaque display area B are integrated into the display panel 110 (which can be referred to as an integrated-type display panel).

For example, both the at least one light-transmissive display area A and the at least one light-opaque display area B disposed in the integrated-type display panel 110 can be driven and controlled by one controller 140 (e.g., the controller 140 in the previous figures discussed above).

Further, data sequences of data signals can include image data supplied to one or more data lines electrically connected to one or more second pixels 510 and one or more first pixels 560, but not include image data for transmissive areas 520.

Particularly, FIG. 12 illustrates that data signals are supplied to corresponding subpixels in the sequence of ‘RBGW . . . RBGW . . . ’. However, example embodiments of the present disclosure are not limited to this, and various sequences of data signals can be supplied to subpixels.

For example, when each pixel included in one row is configured to emit red (R) light, green (G) light, and blue (B) light, data signals corresponding to R color, G color, and B color can be supplied to corresponding subpixels through data lines connected to these subpixels, and when each pixel included in one row is configured to emit R light, G light, B light, and white (W) light, data signals corresponding to R color, G color, B color, and W color can be supplied to corresponding subpixels through data lines connected to these subpixels.

In one or more aspects, unlike the example shown in FIG. 12, the foregoing data signal supply method can be applied to an example where each pixel row is configured with pixels, each of which includes R, G, and B subpixels, without a W subpixel.

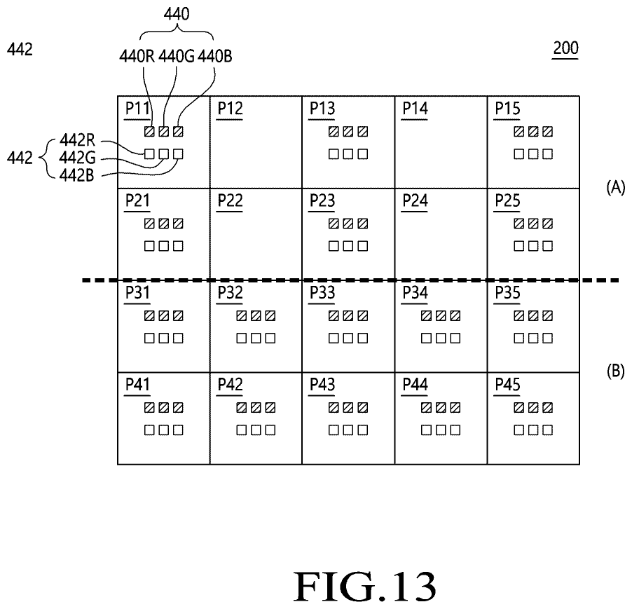

FIG. 13 schematically illustrates an example arrangement of pixels in an example display panel (e.g., a micro LED display panel 200) included in a multi-display device configured with micro LEDs according to aspects of the present disclosure. It should be noted here that two or more micro LED display panels 200 can be included in the multi-display device to provide a large display screen. To enable the multi-display device to operate, at least some of the respective elements of the configurations of at least FIGS. 1 to 4 can be employed mutatis mutandis in the multi-display device of FIG. 13.

Referring to FIG. 13, the micro LED display panel 200 can be manufactured by transferring micro-sized LEDs to a thin film transistor array substrate. The multi-display device including the micro LED display panel 200 is manufactured with complicated process, and thereby, can cause defects such as not emitting light or emitting light abnormally. Such defects can be solved by separately forming one or more redundancy subpixels configured with micro LEDs in a single pixel. In this case, the foregoing data signal supply method can be applied to redundancy subpixels added to cope with the defected micro LEDs.

A plurality of pixel groups configured with micro LEDs can be arranged or combined in a matrix form in the micro LED display panel 200. Each of the plurality of pixel groups included in the micro LED display panel 200 can include a first pixel 440 and a second pixel 442. It should be noted here that although the term “pixel group” is used for ease of understanding, a pixel group is referred to as a pixel. It should be therefore understood such that a pixel P11 can include a first pixel 440 and a second pixel 442. The first pixel 440 can include at least three subpixels configured with at least R, G, and B micro LEDs (440R, 440G, and 440B), which emit R, G, and B light, respectively, and the second pixel 442 can include at least three subpixels configured with at least R, G, and B micro LEDs (442R, 442G, and 442B), which emit R, G, and B light, respectively.

The first pixel 440 or the second pixel 442 can emit white light. The first pixel 440 including the subpixels configured with the R, G, and B micro LEDs (440R, 440G, and 440B) or the second pixel 442 including the subpixels configured with the R, G, and B micro LEDs (442R, 442G, and 442B) can be referred to as a unit pixel. Further, the first pixel 440 and the second pixel 442 can be referred to as a unit pixel or pixel group.

In one or more aspects, a configuration similar to the configuration of the display panel 110 shown in FIG. 4 can be applied to the micro LED display panel 200 of FIG. 13. Accordingly, the micro LED display panel 200 can include a light-transmissive display area A disposed in a first area, and a light-opaque display area B disposed in a second area different from the first area.

The light-transmissive display area A can include a plurality of second pixels or pixel groups (P11, P13, P15, P21, P23, and P25) each including first and second pixels, each of which emits light by corresponding micro LEDs, and a plurality of transmissive areas (P12, P22, P14, and P24) each disposed on one side of at least one of the plurality of second pixels or pixel groups and configured to allow external light to be transmitted.

At least one or more of the plurality of second pixels or pixel groups (P11, P13, P15, P21, P23, and P25) and at least one or more of the plurality of transmissive areas (P12, P22, P14, and P24) included in the light-transmissive display area A can disposed alternately or disposed adjacent to each other in the display panels 200.

The plurality of second pixels or pixel groups (P11, P13, P15, P21, P23, and P25) and the plurality of transmissive areas (P12, P22, P14, and P24) can be disposed alternately on a one-by-one basis in the row direction. However, this configuration can be only an example, and the plurality of second pixels or pixel groups (P11, P13, P15, P21, P23, and P25) and the plurality of transmissive areas (P12, P22, P14, and P24) can be disposed alternately based on a predetermined number in the column direction or in the column and row directions.

Each of subpixels included each of the plurality of second pixels or pixel groups (P11, P13, P15, P21, P23, and P25) can include elements such as at least one thin film transistor, at least one capacitor, a light emitting element such as a micro LED, and the like, and be configured to emit light corresponding to an image signal or image data through the light emitting element using the elements.

Unlike the plurality of second pixels or pixel groups (P11, P13, P15, P21, P23, and P25), the plurality of transmissive areas (P12, P22, P14, and P24) may not include elements such as a thin film transistor, a capacitor, and a light emitting element, and the like, and thus, be areas allowing external light to be transmitted.

Since the light-transmissive display area A includes the plurality of second pixels or pixel groups (P11, P13, P15, P21, P23, and P25) configured to present images and the plurality of transmissive areas (P12, P22, P14, and P24) allowing external light to be transmitted, the multi-display device including the micro LED display panel 200 can provide an advantage of enabling a user to view an external image through the display panel 200 when the user is not viewing an image presented by the display panel 200.

According to the configuration of FIG. 13, since elements, such as a thin film transistor, a capacitor, a light emitting element, and the like, are not disposed in the transmissive areas (P12, P22, P14, and P24), the transmittance of external light passing through the transmissive areas (P12, P22, P14, and P24) can be maximized, and in turn, the transmittance of external light passing through the entire display panel 200 can be improved. Further, the distortion of a transmitted image caused by interference with the elements, such as a thin film transistor, a capacitor, a light emitting element, and the like, can be minimized.

The light-opaque display area B can include a plurality of first pixels or pixel groups (P31 to P45) each including a first pixel and a second pixel, each of which include subpixels, without a transmissive area, and thus, be an area configured to emit light. Each of subpixels included each of the plurality of first pixels or pixel groups (P31 to P45) can include elements such as at least one thin film transistor, at least one capacitor, a light emitting element such as a micro LED, and the like, and be configured to emit light corresponding to a data signal or image data through the light emitting element using the elements. The light-opaque display area B in which the plurality of first pixels or pixel groups (P31 to P45) are disposed may not include a transmissive area allowing external light to be transmitted.

Unlike the light-transmissive display area A, since the light-opaque display area B is an opaque area not including a transmissive area through which external light passes, thus, light cannot pass through this area, and a user cannot see objects or images located on the opposite side.

In one or more aspects, as shown in FIG. 13, the light-transmissive display area A can be located at an upper portion of the display panel 200, and the light-opaque display area B can be located at a lower portion of the display panel 200.

In one or more aspects, contrary to the example of FIG. 13, the light-transmissive display area A can be located at a lower portion of the display panel 200, and the light-opaque display area B can be located at an upper portion of the display panel 200.

In one or more aspects, the light-transmissive display area A can be located at a central portion of the display panel 200, and the light-opaque display area B can be located at one or more areas other than the central portion, for example, one or more side or edge portions of the display panel 200.

In one or more aspects, the light-transmissive display area A can be located at one or more side or edge portions of the display panel 200, and the light-opaque display area B can be located at one or more side or edge portions of the display panel 200 other than the one or more side or edge portions in which the light-transmissive display area A is located.

Referring to FIG. 13, a single pixel or pixel group P for enabling the micro LED display panel 200 to emit light can include a first pixel 440 including first subpixels configured with first micro LEDs (440R, 440G, and 440B) and a second pixel 442 including second subpixels configured with second micro LEDs (442R, 442G, and 442B). The plurality of pixels or pixel groups P disposed in the first row can be disposed, from the left, in the order of P11, P12, P13, P14, and P15, and the plurality of pixels or pixel groups P disposed in the second row can be disposed, from the left, in the order of P21, P22, P23, P24, and P25.

The first micro LEDs (440R, 440G, and 440B) and the second micro LEDs (442R, 442G, and 442B) included in each pixel or pixel group P can be formed in the same structure and have the same light emission characteristics.

In one or more aspects, the first R, G, and B micro LEDs (440R, 440G, and 440B) of each pixel or pixel group can be disposed in the row direction (the x-axis direction) in a corresponding display area of the micro LED display panel 200, and the second R, G, and B micro LEDs (442R, 442G, and 442B) of each pixel or pixel group can be also disposed in the row direction (the x-axis direction) in the corresponding display area.

As described above, during the process of transferring micro LEDs onto a substrate for manufacturing the micro LED display panel 200, there can occur defects in which some micro LEDs do not emit light normally. For example, when the number of LEDs that emit abnormally emit light or do not emit light per predefined area are included in the micro LED display panel 200, such defects can be easily recognized by users.

To solve these defects, in example embodiments of the present disclosure, since the second R, G, and B micro LEDs (442R, 442G, and 442B) are disposed in each pixel or pixel group P of the micro LED display panel 200, thereby, the micro LED display panel 200 can provide advantages of preventing one or more defective pixels from being recognized.

In one or more aspects, the first micro LEDs (440R, 440G, and 440B) included in each pixel or pixel group can be main micro LEDs configured to emit light according to image data applied from outside of the micro LED display panel 200 to present an image, and the second micro LEDs (442R, 442G, and 442B) can be redundancy micro LEDs configured to operate instead of the first micro LEDs (440R, 440G, and 440B) when one or more of the first micro LEDs (440R, 440G, and 440B) become defective. In one or more aspects, the second micro LEDs (442R, 442G, and 442B) can operate as main micro LEDs, and the first micro LEDs (440R, 440G, and 440B) can operate as redundancy micro LEDs.

Further, gate lines, data lines, thin film transistors, and the like for implementing the first micro LEDs (440R, 440G, and 440B) can be disposed in each pixel or pixel group of the micro LED display panel 200, and further, redundant gate lines, redundant data lines, and redundant thin film transistors for driving the second micro LEDs (442R, 442G, and 442B) can be disposed in each pixel or pixel group of the micro LED display panel 200. For example, the first micro LEDs (440R, 440G, and 440B) and the second micro LEDs (442R, 442G, and 442B) operate separately by different thin film transistors, and the like.

For example, image data corresponding to data signals of ‘R-R-G-G-B-B’ can be supplied to first subpixels configured with the first micro LEDs (440R, 440G, and 440B) and second subpixels configured with the second micro LEDs (442R, 442G, and 442B) in each pixel or pixel group of the micro LED display panel 200.

In one or more aspects, the controller 140 can receive image data corresponding to an entire image to be displayed on the display panel 200 and process the image data corresponding to the entire image.

For example, to display distinct images at the respective areas of the display panel or display device based on a difference in resolution between the light-transmissive display area A and the light-opaque display area B of the display panel or display device, the controller 140 can receive arrangement information on the respective areas of the display panel or display device, and process image data corresponding to an entire image to be presented in an entire display area of the display panel or display device based on the arrangement information.

For example, the arrangement information on the respective areas of the display panel or display device can include at least one of the total number, or respective numbers, of light-transmissive display areas A and light-opaque display areas B included in the multi-display device, and respective disposed locations of the light-transmissive display areas A and the light-opaque display areas B.

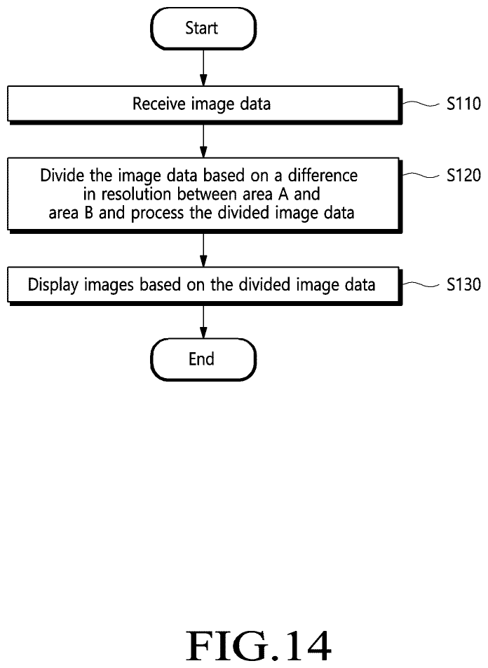

FIG. 14. is a flow diagram for an example image display method of a multi-display device (e.g., any one of the multi-display devices discussed above) according to aspects of the present disclosure.

Referring to FIG. 14, the multi-display device can receive image data to be presented across the entire display area of the multi-display device, at step S110. Thereafter, the multi-display device can divide the received image data based on respective resolutions of at least one light-transmissive display area A and at least one light-opaque display area B, and process the divided image data, which can correspond to the at least one light-transmissive display area A and the at least one light-opaque display area B, respectively, at step S120.

For example, the light-transmissive display area A can have a resolution lower than the light-opaque display area B. In one or more aspects, since the at least one light-transmissive display area A and the at least one light-opaque display area B included in the multi-display device have different resolutions, the multi-display device can determine, among entire image data to be presented across the entire display area of the multi-display device, image data required to be compensated (or one or more values for compensating for the image date) based on respective locations of the at least one light-transmissive display area A and the at least one light-opaque display area B, taking account of a difference in the resolutions.

In one or more aspects, the multi-display device can process entire input image data based on a preset setting by a user or a designer for the at least one light-transmissive display area A and the at least one light-opaque display area B.

Thereafter, the multi-display device can display images corresponding to the divided image data (e.g., images corresponding to compensated image data resulting from compensating for a part of the divided image data and another part of the divided image that is not compensated for) obtained in the previous step in the at least one light-transmissive display area A and the at least one light-opaque display area B, respectively, at step S130.

According to the aspects described herein, a multi-display device can be provided that has a structure in which a transparent display area and an opaque display area are configured in one display panel, and is capable of allowing external light to be transmitted and presenting low-resolution images in an area of the display panel, and is capable of presenting high-resolution images in another area of the display panel.

According to the aspects described herein, a multi-display device can be provided that has a structure in which a transparent display area and an opaque display area are configured in one display panel, and provides a wide range of usages, such as product display, entrance doors, windows, and customer consultation displays.

According to the aspects described herein, a multi-display device can be provided that has a structure in which one controller drives and controls both a transparent display area and an opaque display area, and thereby has a cost-saving effect.

The example embodiments of the present disclosure described above will be briefly described as follows.

According to one or more example embodiments described herein, a multi-display device can include a display panel including a light-transmissive display area disposed in a first area of the display panel and configured to allow external light to be transmitted, and a light-opaque display area disposed in a second area different from the first area; a data driving circuit configured to drive a plurality of data lines across the display panel in a first direction; a gate driving circuit configured to drive a plurality of gate lines across the display panel in a second direction different from the first direction; and a controller configured to supply image data to the data driving circuit. A plurality of first pixels defined by the plurality of data lines and the plurality of gate lines can be disposed in a matrix form in the light-opaque display area, and a plurality of second pixels configured to present an image and a plurality of transmissive areas each disposed on one side of at least one of the plurality of second pixels and configured to allow external light to be transmitted can be disposed in the light-transmissive display area.

In one or more aspects of the present disclosure, the light-transmissive display area can be disposed at an upper portion of the display panel, and the light-opaque display area can be disposed at a lower portion of the display panel.

In one or more aspects of the present disclosure, the multi-display device can include a plurality of light-transmissive display areas and a plurality of light-opaque display areas, and the plurality of light-transmissive display areas and the plurality of light-opaque display areas can be disposed alternately.

In one or more aspects of the present disclosure, all, or one or more (at least one), of the plurality of second pixels and all, or one or more (at least one), of the plurality of transmissive areas can be alternately disposed along one direction and disposed adjacent to each other in the light-transmissive display area.

In one or more aspects of the present disclosure, the gate driving circuit can be configured to sequentially drive one or more gate lines among the plurality of gate lines connected to one or more of the plurality of second pixels disposed in the light-transmissive display area and other one or more gate lines among the plurality of gate lines connected to one or more of the plurality of first pixels disposed in the light-opaque display area, by sequentially supplying a gate signal with a turn-on level voltage to the one or more gate lines and the other one or more gate lines.

In one or more aspects of the present disclosure, when specific gate lines are selected and driven, the data driving circuit can be configured to supply data signals corresponding to the image data to at least one of the plurality of data lines across the light-transmissive display area and the light-opaque display area. The at least one data line connected to at least one subpixel included in at least one of the plurality of second pixels and at least one subpixel included in at least one of the plurality of first pixels can deliver the data signals to the at least one subpixel included in the at least one second pixel and the at least one subpixel included in the at least one first pixel, and may not be electrically connected to at least one of the plurality of transmissive areas disposed in the same column or row as the at least one first pixel or the at least one second pixel.

In one or more aspects of the present disclosure, data sequences of the data signals can include image data supplied to the at least one subpixel included in the at least one first pixel and the at least one subpixel included in the at least one second pixel, and may not include image data for the at least one transmissive area.

In one or more aspects of the present disclosure, the controller can receive image data corresponding to images to be displayed in an entire display area of the multi-display device and process the received image data.

In one or more aspects of the present disclosure, to display distinct images based on a difference in resolution between the light-transmissive display area and the light-opaque display area, the controller can receive arrangement information on respective areas of the multi-display device in which distinct images are presented, and process the image data based on the arrangement information.

In one or more aspects of the present disclosure, the arrangement information on the respective areas of the multi-display device can include at least one of the total number, or respective numbers, of light-transmissive display areas and light-opaque display areas included in the multi-display device, and respective disposed locations of the light-transmissive display areas and the light-opaque display areas.

According to example embodiments described herein, a display panel can include a light-opaque display area disposed in a first area, including a plurality of first pixels or pixel groups each including first subpixels, and configured to emit light; a light-transmissive display area disposed in a second area different from the first area, and including a plurality of second pixels or pixel groups each including second subpixels and configured to present an image, and a plurality of transmissive areas each disposed on one side of at least one of the plurality of second pixels or pixel groups and configured to allow external light to be transmitted; a plurality of data lines extending along at least one of the plurality of first pixels or pixel groups and at least one of the plurality of transmissive areas; and a plurality of gate lines extending along one or more first or second pixels or pixel groups in a second direction different from the first direction.

In one or more aspects of the present disclosure, the light-transmissive display area can be disposed at an upper portion of the display panel, and the light-opaque display area can be disposed at a lower portion of the display panel.

In one or more aspects of the present disclosure, the display panel can include a plurality of light-transmissive display areas and a plurality of light-opaque display areas, and the plurality of light-transmissive display areas and the plurality of light-opaque display areas can be disposed alternately.

In one or more aspects of the present disclosure, one or more of the plurality of second pixels or pixel groups and one or more of the plurality of transmissive areas can be disposed alternately along one direction and be disposed adjacent to each other in the light-transmissive display area.

In one or more aspects of the present disclosure, each of the plurality of gate lines can receive a gate signal with a turn-on level voltage, and one or more gate lines among the plurality of gate lines connected to one or more of the plurality of second pixels or pixel groups disposed in the light-transmissive display area and other one or more gate lines among the plurality of gate lines connected to one or more of the plurality of first pixels or pixel groups disposed in the light-opaque display area can be sequentially driven.

In one or more aspects of the present disclosure, when specific gate lines are selected and driven, at least one of the plurality of data lines across the light-transmissive display area and the light-opaque display area can receive data signals from a controller. The at least one data line connected to at least one subpixel included in at least one of the plurality of second pixels or pixel groups and at least one subpixel included in at least one of the plurality of first pixels or pixel groups can deliver the data signals to the at least one subpixel included in the at least one second pixel or pixel group and the at least one subpixel included in the at least one first pixel or pixel group, and may not be electrically connected to at least one of the plurality of transmissive areas disposed in the same column or row as the at least one first pixel or pixel group or the at least one second pixel or pixel group.

In one or more aspects of the present disclosure, data sequences of the data signals can include image data supplied to the at least one subpixel included in the at least one first pixel group or pixel group and the at least one subpixel included in the at least one second pixel or pixel group, and not comprise image data for the at least one transmissive area.

In one or more aspects of the present disclosure, image data corresponding to images to be displayed in an entire display area of the display panel can be received and processed by a controller.

In one or more aspects of the present disclosure, to display distinct images based on a difference in resolution between the light-transmissive display area and the light-opaque display area, arrangement information on respective areas of the display panel in which distinct images are presented can be received by the controller, and the image data can be process by the controller based on the arrangement information.

In one or more aspects of the present disclosure, the arrangement information on the respective areas of the multi-display device can include at least one of the total number, or respective numbers, of light-transmissive display areas and light-opaque display areas included in the multi-display device, and respective disposed locations of the light-transmissive display areas and the light-opaque display areas.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein can be applied to other embodiments and applications without departing from the scope of the present invention. The above description and the accompanying drawings provide examples of the technical features of the present invention for illustrative purposes only. For example, the disclosed embodiments are intended to illustrate the scope of the technical features of the present invention.

What is claimed is:

1. A multi-display device comprising:
a display panel including a light-transmissive display area disposed in a first area of the display panel and a light-opaque display area disposed in a second area different from the first area, the light-transmissive display area being configured to allow external light to be transmitted;
a data driving circuit configured to drive a plurality of data lines disposed across the display panel in a first direction;
a gate driving circuit configured to drive a plurality of gate lines disposed across the display panel in a second direction different from the first direction; and
a controller configured to supply image data to the data driving circuit,
wherein a plurality of first pixels defined by the plurality of data lines and the plurality of gate lines are disposed in a matrix form in the light-opaque display area, and
wherein a plurality of second pixels configured to present an image and a plurality of transmissive areas each disposed on one side of at least one of the plurality of second pixels and configured to allow external light to be transmitted are disposed in the light-transmissive display area.

2. The multi-display device of claim 1, wherein the light-transmissive display area is disposed at an upper portion of the display panel, and the light-opaque display area is disposed at a lower portion of the display panel.

3. The multi-display device of claim 1, wherein in the light-transmissive display area, at least one of the plurality of second pixels and at least one of the plurality of transmissive areas are alternately disposed along one direction and disposed adjacent to each other.

4. The multi-display device of claim 1, wherein the gate driving circuit is configured to sequentially drive one or more gate lines among the plurality of gate lines connected to one or more of the plurality of second pixels disposed in the light-transmissive display area and other one or more gate lines among the plurality of gate lines connected to one or more of the plurality of first pixels disposed in the light-opaque display area, by sequentially supplying a gate signal with a turn-on level voltage to the one or more gate lines and the other one or more gate lines.

5. The multi-display device of claim 4, wherein when specific gate lines are selected and driven, the data driving circuit is configured to supply data signals corresponding to the image data to at least one data line of the plurality of data lines across the light-transmissive display area and the light-opaque display area, and
wherein the at least one data line connected to at least one subpixel included in at least one of the plurality of second pixels and at least one subpixel included in at least one of the plurality of first pixels delivers the data signals to the at least one subpixel included in the at least one second pixel and the at least one subpixel included in the at least one first pixel, and is not electrically connected to at least one of the plurality of transmissive areas disposed in a same column or row as the at least one first pixel or the at least one second pixel.

6. The multi-display device of claim 5, wherein data sequences of the data signals comprise image data supplied to the at least one subpixel included in the at least one first pixel and the at least one subpixel included in the at least one second pixel, and do not comprise image data for the at least one transmissive area.

7. The multi-display device of claim 1, wherein the controller receives the image data corresponding to images to be displayed in an entire display area of the multi-display device and processes the received image data.

8. The multi-display device of claim 7, wherein to display distinct images based on a difference in resolution between the light-transmissive display area and the light-opaque display area, the controller receives arrangement information on respective areas of the multi-display device in which distinct images are presented, and processes the image data based on the arrangement information.

9. The multi-display device of claim 8, wherein the arrangement information on the respective areas of the multi-display device comprises at least one of a total number, or respective numbers, of light-transmissive display areas and light-opaque display areas included in the multi-display device, and respective disposed locations of the light-transmissive display areas and the light-opaque display areas.

10. A display panel comprising:
a light-opaque display area disposed in a first area, including a plurality of first pixels or pixel groups each including first subpixels, and configured to emit light;
a light-transmissive display area disposed in a second area different from the first area, and including a plurality of second pixels or pixel groups each including second subpixels and configured to present an image, and a plurality of transmissive areas each disposed on one side of at least one of the plurality of second pixels or pixel groups and configured to allow external light to be transmitted;
a plurality of data lines extending along at least one of the plurality of first pixels or pixel groups and at least one of the plurality of transmissive areas; and
a plurality of gate lines extending along one or more first or second pixels or pixel groups in a second direction different from the first direction.

11. The display panel of claim 10, wherein the light-transmissive display area is disposed at an upper portion of the display panel, and the light-opaque display area is disposed at a lower portion of the display panel.

12. The display panel of claim 10, wherein one or more of the plurality of second pixels or pixel groups and one or more of the plurality of transmissive areas are disposed alternately along one direction and disposed adjacent to each other in the light-transmissive display area.

13. The display panel of claim 10, wherein each of the plurality of gate lines receives a gate signal with a turn-on level voltage, and
wherein one or more gate lines among the plurality of gate lines connected to one or more of the plurality of second pixels or pixel groups disposed in the light-transmissive display area and other one or more gate lines among the plurality of gate lines connected to one or more of the plurality of first pixels or pixel groups disposed in the light-opaque display area are sequentially driven.

14. The display panel of claim 13, wherein when specific gate lines are selected and driven, at least one of the plurality of data lines across the light-transmissive display area and the light-opaque display area receives data signals from a controller, and
wherein the at least one data line connected to at least one subpixel included in at least one of the plurality of second pixels or pixel groups and at least one subpixel included in at least one of the plurality of first pixels or pixel groups delivers the data signals to the at least one subpixel included in the at least one second pixel or pixel group and the at least one subpixel included in the at least one first pixel or pixel group, and is not electrically connected to at least one of the plurality of transmissive areas disposed in the same column or row as the at least one first pixel or pixel group or the at least one second pixel or pixel group.

15. The display panel of claim 14, wherein data sequences of the data signals comprise image data supplied to the at least one subpixel included in the at least one first pixel group or pixel group and the at least one subpixel included in the at least one second pixel or pixel group, and do not comprise image data for the at least one transmissive area.

16. The display panel of claim 15, wherein image data corresponding to images to be displayed in an entire display area of the display panel are received and processed by the controller.

17. The display panel of claim 14, wherein to display distinct images based on a difference in resolution between the light-transmissive display area and the light-opaque display area, arrangement information on respective areas of the display panel in which distinct images are presented is received by the controller, and the image data are processed by the controller based on the arrangement information.

18. The display panel of claim 17, wherein the arrangement information on the respective areas of the display panel comprises at least one of a total number, or respective numbers, of light-transmissive display areas and light-opaque display areas included in the multi-display device, and respective disposed locations of the light-transmissive display areas and the light-opaque display areas.
